(19) United States
(12) Patent Application Publication
(10) Pub. No.: US 2005/0057144 A1
(43) Pub. Date: Mar. 17, 2005

(54) Semiconductor light-emitting device

(76) Inventors: Yasumasa Morita, Tokyo (JP); Hayato Oba, Tokyo (JP); Shigeo Fujisawa, Tokyo (JP); Minoru Tanaka, Tokyo (JP)

Correspondence Address: CERMAK & KENEALY, LLP, 23 W. Myrtle St, Alexandria, VA, 22301, US

(21) Appl. No.: 10/901,991

(22) Filed: Jul. 30, 2004

(30) Foreign Application Priority Data
Sep. 17, 2003 (JP) 2003-324884

(51) Int. Cl. H01L 33/00

(52) U.S. Cl. 313/501; 313/498; 313/512

(57) ABSTRACT

A semiconductor light-emitting device can serve as a high-brightness light source with less tone variation. A reflective frame having a conical recess can be provided on a substrate. An LED chip can be mounted on the bottom in the reflective frame. A wavelength converter material is preferably filled in the recess to seal the LED chip. The wavelength converter material can include a fluorescent material and a 20-80 wt. % diffuser mixed in an optically transmissive resin.

This invention claims the benefit of Japanese patent application No. 2003-324884, filed on Sep. 17, 2003, which is hereby incorporated by reference.

### BACKGROUND OF THE INVENTION

1. Field of the Invention

The present invention relates to a semiconductor light-emitting device. More particularly, it relates to a semiconductor light-emitting device operative to provide toned light through mixture of light emitted from a semiconductor light-emitting element (light-emitting diode chip) with light emitted from the light-emitting diode chip that is wavelength-converted at a fluorescent material in combination.

2. Description of the Related Art

A light-emitting diode (LED) chip operative to emit a light having a sharp spectrum distribution characteristic can be employed as a light source to achieve an LED that emits a white light. In this case, the light emitted from the LED chip can be mixed with a wavelength-converted light emitted/caused by a fluorescent material when the light emitted from the LED chip excites the fluorescent material. For example, when the light emitted from the LED chip is a blue light, a fluorescent material can be employed that wavelength-converts the blue light into its complementary yellow light when it is excited with the blue light. In this case, the blue light emitted from the LED chip excites the fluorescent material to create a wavelength-converted yellow light, which can be mixed with the blue light emitted from the LED chip to yield a white light. In another example, when the light emitted from the LED chip is blue light, two different fluorescent materials may be employed in mixture that can wavelength-convert the blue light into respective green and red lights when they are excited with the blue light. In this case, the blue light emitted from the LED chip excites the fluorescent materials to create the wavelength-converted green and red lights, which can be mixed with the blue light emitted from the LED chip to yield a white light. If the light emitted from the LED chip is an ultraviolet light, three different fluorescent materials may be employed in mixture that can wavelength-convert the ultraviolet light into respective blue, green and red lights when they are excited with the ultraviolet light. In this case, the ultraviolet light emitted from the LED chip excites the fluorescent materials to create the wavelength-converted blue, green and red lights, which can be mixed with each other to yield a white light. Further, appropriate combinations of the emission color of the light from the LED chip with the fluorescent material(s) can create various emission colors other than white light.

In an LED that excites fluorescent material with the light emitted from the light source for wavelength conversion to provide a differently toned light compared to the light emitted from the light source, the fluorescent material is generally mixed in an optically transmissive resin for use. A diffuser may be mixed together with the fluorescent material. For example, an LED lamp can be configured with the use of a wavelength converter material that contains a fluorescent material and a 5-20 wt. % diffuser mixed in an optically transmissive resin to seal an LED chip mounted on one end of paired lead frames.

In an LED that is structured to seal the LED chip in a wavelength converter material that contains fluorescent material mixed in optically transmissive resin, the fluorescent material may comprise an organic fluorescent material. In such a case, the fluorescent material can deteriorate over time because it receives ultraviolet and visible lights contained in the light emitted from the LED chip and extraneous light such as sunlight. As a result, some problems arise because the tone of the light emitted from the LED is shifted and the amount of the light is lowered.

To solve such problems, the LED chip may be sealed in a wavelength converter material that contains a diffuser in addition to the fluorescent material mixed in the optically transmissive resin. In this case, light that enters into the wavelength converter material is divided into light directed to the fluorescent material and light directed to the diffuser to decrease a proportion of the light directed to the fluorescent material. At the same time, a low-brightness light scattered at the diffuser is directed to the fluorescent material. As a result, the deterioration of the fluorescent material can be slowed, and improvement in the shift of the tone of the light emitted from the LED and the brightness retainability can be realized. (For example, see Japanese Patent JP-3065544, page 2, FIG. 1, the entire disclosure of which is hereby incorporated by reference).

The conventional LED described above, however, has the main purpose of reducing the deterioration of the fluorescent material to reduce the variations in tone and amount of light emitted from the LED over time. However, there are not sufficient measures for ensuring the amount of light and for reducing the variation in tone.

The present invention has been made in consideration of the above and other problems, and accordingly includes embodiments that provide a light-emitting diode serving as a reliable high-brightness light source with less tone variation.

### SUMMARY OF THE INVENTION

To solve the above and other problems, an aspect of the present invention is directed to a semiconductor light-emitting device, comprising: at least one light-emitting diode chip; and a wavelength converter material arranged to seal the light-emitting diode chip, the wavelength converter material containing at least one fluorescent material and a diffuser mixed in an optically transmissive resin, wherein the diffuser is mixed in the wavelength converter material by an amount equal to 20-80 wt. % thereof.

Another aspect of the invention includes a semiconductor light-emitting device, wherein the light-emitting diode chip emits an ultraviolet light.

Another aspect of the invention includes a semiconductor light-emitting device wherein the light-emitting diode chip emits a blue light or a green light.

Another aspect of the invention includes a semiconductor light-emitting device wherein the light-emitting diode chips include a light-emitting diode chip operative to emit a blue light and a light-emitting diode chip operative to emit a green light.

Another aspect of the invention includes a semiconductor light-emitting device, wherein the fluorescent material consists of one selected among an aluminate doped with a rare earth element; a thiogallate doped with a rare earth element; and an orthosilicate doped with a rare earth element.

Another aspect of the invention includes a semiconductor light-emitting device, wherein the optically transmissive resin consists of one selected among an epoxy resin, a silicone resin, an acrylic resin and a cycloolefin resin.

Another aspect of the invention includes a plurality of light-emitting diode chips located in the wavelength converter material.

Another aspect of the invention includes a transparent resinous lens located adjacent the light-emitting diode chip. In addition, it is possible to include a wavelength converter material, a diffuser, and/or a fluorescent material in the transparent resinous lens.

### BRIEF DESCRIPTION OF THE DRAWINGS

The present invention will be more fully understood from the following detailed description with reference to the accompanying drawings, in which:

FIG. 1 is a cross-sectional view of a semiconductor light-emitting device according to a preferred embodiment of the invention;

FIG. 2 is a schematic diagram illustrative of optical paths in the semiconductor light-emitting device according to the embodiment of FIG. 1;

FIG. 3 is a cross-sectional view of a semiconductor light-emitting device according to another preferred embodiment of the invention; and

FIG. 4 is a cross-sectional view of a semiconductor light-emitting device according to another preferred embodiment of the invention.

### DETAILED DESCRIPTION OF PREFERRED EMBODIMENTS

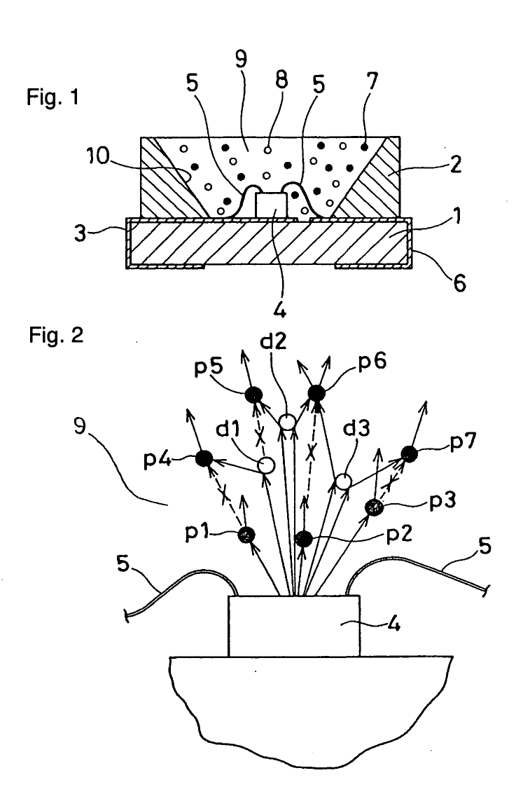

A semiconductor light-emitting device that serves as a high-brightness light source with less tone variation can be achieved with an arrangement that seals a light-emitting diode chip in a wavelength converter material, which contains a fluorescent material and a 20-80 wt.% diffuser mixed in an optically transmissive resin. Preferred embodiments of the present invention will be described in detail below with reference to FIGS. 1-4 (denoting the same portions with the same reference numerals). It should be appreciated that the described embodiments are simply specified examples, which are given various preferable technical limitations. Accordingly, the scope of the present invention is not limited by these embodiments.

Embodiment of FIG. 1

FIG. 1 is a cross-sectional view showing the structure of a semiconductor light-emitting device according to a preferred embodiment of the invention. The embodiment of FIG. 1 is directed to an LED configuration that is commonly referred to as a surface-mounted type. A substrate 1 can include circuit pattern(s) formed on surfaces thereof. A reflective frame 2 having a conical recess can be provided on the circuit pattern(s). An LED chip 4 can be mounted on a first circuit pattern 3 at the bottom of the recess. Two electrodes can be formed on the upper surface of the LED chip 4. One of the electrodes can be connected to the first circuit pattern 3 via a bonding wire 5 to achieve electrical conduction therebetween. The other electrode can be connected to a second circuit pattern 6, separated from the first circuit pattern 3, via a bonding wire 5 to achieve electrical conduction therebetween. A wavelength converter material 9, which can contain a fluorescent material 7 and a 20-80 wt. % diffuser 8 mixed in an optically transmissive resin, can be filled in the recess formed in the reflective frame 2 to seal the LED chip 4. The reflective frame 2 is preferably composed of a highly reflective material to form a reflective inner surface 10 in the recess without application of special reflective processing. Alternatively, the reflective inner surface 10 may be formed in the recess by evaporating or painting a highly reflective material such as aluminum and/or silver thereon.

FIG. 2 schematically shows how light emitted from the LED chip 4 that enters into the wavelength converter material 9 suffers actions from the fluorescent material 7 and the diffuser 8 in the LED thus configured. It also shows a possible optical relation between the fluorescent material 7 and the diffuser 8. The light emitted from the LED chip 4 that enters into the wavelength converter material 9 can be directly received at the fluorescent material particles p1, p2 and p3, which provide wavelength-converted light with longer wavelengths than that of the received light when they are excited by the received light. The fluorescent material particles p4, p6 and p7 can not directly receive the light emitted from the LED chip 4 because they are located behind the fluorescent material particles p1, p2 and p3 (as shown with dotted lines in FIG. 2). The fluorescent material particle p5 can not directly receive the light emitted from the LED chip 4 because it is located behind the diffuser particle d1 (as shown with the dotted line in FIG. 2). These fluorescent material particles p4, p6, p7 and p5 receive scattered light from the diffuser particle d1, scattered light from the diffuser particles d2 and d3, scattered light from the diffuser particle d3, and scattered light from the diffuser particle d2, respectively. They can provide wavelength-converted light with longer wavelengths than that of the received light when they are excited with the received light.

The fluorescent material contained in the wavelength converter material can receive light emitted from the LED chip, light scattered from a single diffuser particle, and multiple rays of light scattered from multiple diffuser particles, in combination. Thus, the fluorescent material can provide a wavelength-converted light with a longer wavelength than that of the received light when it is excited with the received light.

Though it is not shown in FIG. 2, two or more fluorescent materials may be contained in the wavelength converter material to cause a chain reaction, in which a wavelength-converted light from a fluorescent material excites a different type of fluorescent material for further wavelength conversion. In this case, at each process of the chained wavelength conversions, a part of the wavelength-converted light can be emitted directly to the outside of the lighting device. In addition, at each process, the fluorescent material may suffer effects from multiple scattered lights from one or more diffusers. Further, the fluorescent material may be excited with the light having mixed multiple wavelengths.

Thus, the light emitted from the LED chip forms a stream of light with complicated associations between the fluorescent material and the diffuser. Light rays having various wavelengths present inside the wavelength converter material can be mixed and dispersed to provide light with less tone variations that is emitted externally.

The diffuser can be mixed in the wavelength converter material at a relatively higher density such as 20-80 wt. % together with the fluorescent material. Even if the fluorescent material particle can not directly receive the light emitted from the LED chip, it can receive the light rays that are scattered from multiple diffuser particles. Accordingly, it is possible to provide a high-brightness LED with excellent wavelength conversion efficiency.

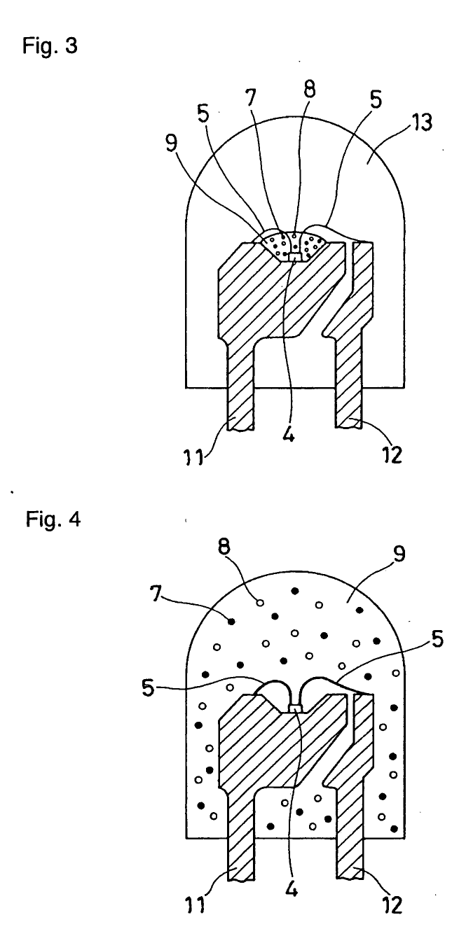

Embodiment of FIG. 3

FIG. 3 is a cross-sectional view showing the structure of a semiconductor light-emitting device according to another embodiment of the present invention. The embodiment is directed to an LED configuration commonly referred to as a shell-type, which can include two lead frames 11, 12. At the tip of one of the lead frames, a conical recess having a reflective inner side can be formed. An LED chip 4 is preferably mounted on the bottom in the recess. Two electrodes can be provided on the upper surface of the LED chip 4. One of the electrodes can be connected to the lead frame 11 via a bonding wire 5 to achieve electrical conduction therebetween. The other electrode can be connected to the lead frame 12 via a bonding wire 5 to achieve electrical conduction therebetween. A wavelength converter material 9, which can contain a fluorescent material 7 and a 20-80 wt. % diffuser 8 mixed in an optically transmissive resin, can be placed/filled in the recess with the LED chip 4 mounted therein, to seal or attach the LED chip 4. The tip of the lead frame 11 with the LED chip 4 mounted thereon can be covered with a transparent resinous lens 13.

The wavelength converter material 9 of the present embodiment filled in the recess with the LED chip 4 mounted therein can act in the same manner as the contents described above with reference to the embodiment of FIG. 1. In the embodiment of FIG. 3, the tip of the lead frame 11 with the LED chip 4 mounted thereon can be covered with a transparent resinous lens 13 that is convex. This is effective to protect the bonding wires 5 from extraneous stresses such as vibrations and impacts. This is also effective to protect the fluorescent material 7 and the diffuser 8 mixed in the wavelength converter material 9 from external environments, such as humidity, and mechanical frictions. Further, the lens 13 has a lens effect so as to collect light which is emitted from the LED chip 4, and which is led through and wavelength-converted at the wavelength converter material 9, before the light is externally emitted.

Embodiment of FIG. 4

FIG. 4 is a cross-sectional view showing the structure of a semiconductor light-emitting device according to another embodiment of the present invention. The embodiment of FIG. 4 is also directed to a shell-type LED similar to the embodiment of FIG. 3 described above. At the tip of one of two lead frames 11, 12, a conical recess having a reflective inner side can be formed. An LED chip 4 is preferably mounted on the bottom in the recess. Two electrodes can be provided on the upper surface of the LED chip 4. One of the electrodes can be connected to the lead frame 11 via a bonding wire 5 to achieve electrical conduction therebetween. The other electrode can be connected to the lead frame 12 via a bonding wire 5 to achieve electrical conduction therebetween. The tip of the lead frame 11 with the LED chip 4 mounted thereon can be covered with a wavelength converter material 9, which preferably contains a fluorescent material 7 and a 20-80 wt. % diffuser 8 mixed in an optically transmissive resin, to form a convex lens.

In the embodiment of FIG. 4, the tip of the lead frame 11 with the LED chip 4 mounted thereon can be covered with the wavelength converter material 9 containing the fluorescent material 7 and the 20-80 wt. % diffuser 8 in mixture to form a convex lens. The wavelength converter material 9 can act in the same manner as described above with reference to the embodiment of FIG. 1. In this case, however, the wavelength converter material 9 can seal the tip of the lead frame 11 together with the LED chip 4 mounted thereon, resulting in reduction of the process steps, which contributes to lowering the production cost.

In the above described preferred embodiments of the invention, the optically transmissive resin is preferably selected among an epoxy resin, a silicone resin, an acrylic resin and a cycloolefin resin. The fluorescent material is preferably selected among: an aluminate doped with a rare earth element; a thiogallate doped with a rare earth element; and, an orthosilicate doped with a rare earth element. The diffuser is preferably selected among titania, alumina, and silica.

Together with the fluorescent material, the diffuser can be mixed in the optically transmissive resin by an amount equal to or between 20-80 wt. % thereof. If the amount is below 20 wt.%, the mixture of the diffuser is not expected to provide a sufficient effect with regard to achieving high brightness. If the amount is above 80 wt. %, the optically transmissive resin has a high viscosity and turns into a very hard paste that is hardly treatable. In addition, it has lowered adhesion and has problems functioning as a sealing resin.

For use in the preferred embodiments of the present invention, the LED chip can be selected from among three types of LED chips that emit ultraviolet, blue and green lights so as to achieve a desired tone for the LED in combination with various fluorescent materials. In this case, the LED chip can be employed solely or in combination with other LED chips with different emission colors. The ultraviolet LED chip is preferably solely employed. To the contrary, the blue LED chip and the green LED chip can be either solely employed or employed in combination.

As described above, the semiconductor light-emitting device can be sealed in the wavelength-converter material. The wavelength-converter material preferably contains the fluorescent material and the diffuser mixed in the optically transmissive resin. The fluorescent material can be mixed to receive light and wavelength-convert the received light into light with a longer wavelength compared to the received light. The diffuser can be mixed to receive light and scatter the received light. Therefore, the rays of light received at the fluorescent material can include: the light emitted from the LED chip; the light emitted from the LED chip and scattered from the diffuser; the light that is wavelength-converted at different types of fluorescent materials; and the light that is wavelength-converted at different types of fluorescent materials and scattered from the diffuser. Particularly, the diffuser can be mixed in the optically transmissive resin at a relatively higher density, such as 20-80 wt. %. This enables the fluorescent material to receive the light scattered from the diffuser at a high proportion. As a result, the amount of the light wavelength-converted at the fluorescent material can be increased so as to achieve a high-brightness LED.

Various lights having various types of mixed wavelengths can enter the fluorescent material from various directions through various optical paths and can be wavelength-converted and emitted/reflected/directed in various directions. Therefore, the wavelength-converted and mixed light within the wavelength-converter material can be dispersed so as to achieve an LED that emits a light with less tone variation.

A high density of the diffuser having a lower thermal expansion coefficient than that of the optical transmissive resin can reduce an occupation ratio of the optical transmissive resin in the wavelength-converter material. This reduces the absolute expansion volume of the optical transmissive resin and decreases the thermal expansion coefficient of the wavelength-converter material. Malfunctions such as a broken LED chip and a cut bonding wire may be caused by stress when the sealing resin expands due to the external heat imparted onto an LED during LED mounting by solder reflow, for example. The heat radiated from the LED chip during LED lighting also expands the sealing resin. Excellent effects can be achieved because it is possible to reduce factors that cause the malfunctions and to improve the reliability of the LED.

Having described preferred embodiments that are consistent with the invention, other embodiments and variations consistent with the invention will be apparent to those skilled in the art. Therefore, the invention should not be viewed as limited to the disclosed preferred embodiments, but rather should be viewed as limited only by the spirit and scope of the appended claims.

1. A semiconductor light-emitting device, comprising:
at least one light-emitting diode chip; and
a wavelength converter material arranged to seal said at least one light-emitting diode chip, said wavelength converter material including at least one fluorescent material and a diffuser mixed in an optically transmissive resin, wherein said diffuser is mixed in said wavelength converter material by an amount equal to 20-80 wt. % thereof.

2. The semiconductor light-emitting device according to claim 1, wherein said light-emitting diode chip emits an ultraviolet light.

3. The semiconductor light-emitting device according to claim 1, wherein said light-emitting diode chip emits one of a blue light and a green light.

4. The semiconductor light-emitting device according to claim 1, wherein said at least one light-emitting diode chip includes a light-emitting diode chip that emits a blue light and a light-emitting diode chip that emits a green light.

5. The semiconductor light-emitting device according to claim 1, wherein said fluorescent material is selected from the group consisting of: an aluminate doped with a rare earth element; a thiogallate doped with a rare earth element; and, an orthosilicate doped with a rare earth element.

6. The semiconductor light-emitting device according to claim 1, wherein said optically transmissive resin is selected from the group consisting of: an epoxy resin; a silicone resin; an acrylic resin; and, a cycloolefin resin.

7. The semiconductor light-emitting device according to claim 2, wherein said fluorescent material is selected from the group consisting of an aluminate doped with a rare earth element; a thiogallate doped with a rare earth element; and, an orthosilicate doped with a rare earth element.

8. The semiconductor light-emitting device according to claim 3, wherein said fluorescent material is selected from the group consisting of: an aluminate doped with a rare earth element; a thiogallate doped with a rare earth element; and, an orthosilicate doped with a rare earth element.

9. The semiconductor light-emitting device according to claim 4, wherein said fluorescent material is selected from the group consisting of: an aluminate doped with a rare earth element; a thiogallate doped with a rare earth element; and, an orthosilicate doped with a rare earth element.

10. The semiconductor light-emitting device according to claim 2, wherein said optically transmissive resin is selected from the group consisting of: an epoxy resin; a silicone resin; an acrylic resin; and, a cycloolefin resin.

11. The semiconductor light-emitting device according to claim 3, wherein said optically transmissive resin is selected from the group consisting of: an epoxy resin; a silicone resin; an acrylic resin; and, a cycloolefin resin.

12. The semiconductor light-emitting device according to claim 4, wherein said optically transmissive resin is selected from the group consisting of: an epoxy resin; a silicone resin; an acrylic resin; and, a cycloolefin resin.

13. The semiconductor light-emitting device according to claim 5, wherein said optically transmissive resin is selected from the group consisting of: an epoxy resin; a silicone resin; an acrylic resin; and, a cycloolefin resin.

14. The semiconductor light-emitting device according to claim 1, wherein said at least one light-emitting diode chip includes a plurality of light-emitting diode chips.

15. The semiconductor light-emitting device according to claim 1, further comprising:
a transparent resinous convex lens located adjacent the light-emitting diode chip.

16. The semiconductor light-emitting device according to claim 1, wherein said wavelength converter material is shaped as a convex lens.

17. A light-emitting device, comprising:
a light-emitting diode chip; and
a wavelength converter material adjacent said light-emitting diode chip, said wavelength converter material including a fluorescent material and a diffuser mixed in an optically transmissive resin, wherein said diffuser is mixed in said wavelength converter material by an amount between 20-80 wt. %.

18. The semiconductor light-emitting device according to claim 17, wherein said optically transmissive resin is selected from the group consisting of: an epoxy resin; a silicone resin; an acrylic resin; and, a cycloolefin resin.

19. The semiconductor light-emitting device according to claim 17, wherein said fluorescent material is selected from the group consisting of: an aluminate doped with a rare earth element; a thiogallate doped with a rare earth element; and, an orthosilicate doped with a rare earth element.

20. The semiconductor light-emitting device according to claim 17, wherein said diffuser includes one of titania, alumina, and silica.
